(19) United States
(12) Patent Application Publication
(10) Pub. No.: US 2021/0223604 A1
(43) Pub. Date: Jul. 22, 2021

(54) OPTICAL FILM AND FABRICATION METHOD THEREOF AND DISPLAY APPARATUS

(71) Applicants: BOE TECHNOLOGY GROUP CO., LTD., Beijing (CN); HEFEI BOE OPTOELECTRONICS TECHNOLOGY CO., LTD., Hefei, Anhui (CN)

(72) Inventors: Xianxue DUAN, Beijing (CN); Kui GONG, Beijing (CN)

(73) Assignees: BOE Technology Group Co., Ltd., Beijing (CN); Hefei BOE Optoelectronics Technology Co., Ltd., Hefei, Anhui (CN)

(21) Appl. No.: 15/778,392

(22) PCT Filed: Dec. 5, 2017
(86) PCT No.: PCT/CN2017/114580

§ 371 Date: May 23, 2018

(30) Foreign Application Priority Data
Mar. 3, 2017 (CN) 201710123457.5

(51) Int. Cl. G02F 1/1333; G02B 27/00; C23C 14/08; C23C 14/35; G03F 7/00

(52) U.S. Cl. CPC G02F 1/133357; G02B 27/0081; G02F 2202/16; C23C 14/35; G03F 7/0005; C23C 14/086

(57) ABSTRACT

The present disclosure is related to an optical film. The optical film may include a substrate and a planarization layer. A plurality of cavities may be on a surface of the substrate. A cross-sectional area of each of the cavities parallel to a bottom surface thereof may increase along a direction away from the bottom surface. The planarization layer may be on the surface of the substrate having the cavities. A refractive index of the planarization layer may be larger than that of the substrate.

### CROSS-REFERENCE TO RELATED APPLICATIONS

This application claims benefit of the filing date of Chinese Patent Application No. 201710123457.5 filed on Mar. 3, 2017, the disclosure of which is hereby incorporated by reference.

### TECHNICAL FIELD

The present invention relates to a display technology and, more particularly, to an optical film, a method of fabricating, the same, and a display apparatus.

### BACKGROUND

One problem with a traditional process of fabricating a thin film transistor liquid crystal display (TFT-LCD) is that when light from a backlight source passes through a polarizer or a thin film transistor (TFT) etc., the outputted light has a certain direction. That is, most of the light is emitted from a screen vertically. Accordingly, when watching from a large viewing angle, people cannot see original colors from the LCD, or even can only see all black or all white. In particular, a TFT-LCD display in a Twist Nematic (TN) mode has a small viewing angle due to special rotation mode of liquid crystals. Its display quality declines significantly as the viewing angle increases. As people pursue high display quality, requirements for a TFT-LCD are getting higher and higher.

### BRIEF SUMMARY

Accordingly, one example of the present disclosure is an optical film. The optical film may comprise a substrate and a planarization layer. A plurality of cavities may be provided on a surface of the substrate, a cross-sectional area of each of the cavities parallel to a bottom surface thereof increases along a direction away from the bottom surface. The planarization layer may be on the surface of the substrate having, the cavities, and a refractive index of the planarization layer may be larger than a refractive index of the substrate. The plurality of cavities may be arranged in an array. The cavities each may have a shape of a regular polygonal prism. The regular polygonal prism may be a regular quadrangular prism. A length L of a side of a positive projection of each of the cavities on the substrate may be substantially equal to a distance L′ between two adjacent cavities on the substrate. L and L′ each may be approximately in a range between 1 μm and 5 μm. An angle between a side surface of each of the cavities and the bottom surface thereof may be approximately in a range between 110° to 150°. A depth of each of the cavities may be approximately in a range between 500 nm to 1 μm. A thickness of the planarization layer may be approximately in a range between 1 μm to 2 μm. The planarization layer may at least fill and level up the cavities. A surface of the planarization layer may be substantially parallel to the bottom surface of each of the cavities. The planarization layer may be made of a transparent conductive material, the transparent conductive material may be indium tin oxide.

Another example of the present disclosure is a display substrate comprising the optical film according to one embodiment of the present disclosure. The display substrate may further comprise a color film layer on a side of the substrate away from the cavities. Another example of the present disclosure is a display apparatus comprising the display substrate according to one embodiment of the present disclosure.

Another example of the present disclosure is a method for fabricating an optical film. The method may comprise providing a substrate; forming a cavity on a surface of the substrate, wherein a cross-sectional area of the cavity parallel to a bottom surface of the cavity increases along a direction away from the bottom surface; and forming, a planarization layer on the surface of the substrate having the cavity. Forming the cavity on the surface of the substrate may comprise coating a layer of photoresist on the surface of the substrate and forming photoresist retention regions and photoresist non-retention regions on the substrate; etching the photoresist non-retention regions to form the cavity by a plasma etching apparatus; and removing the photoresist at the photoresist retention regions, Forming the planarization layer on the surface of the substrate having the cavity may comprise forming the planarization layer on the surface of the substrate having the cavity by a magnetron sputtering method.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is a plan view of an optical film according to one embodiment of the present disclosure;

FIG. 2a is a cross-sectional view along a line A-B shown M FIG. 1 according to one embodiment of the present disclosure; FIG. 2b is a cross-sectional view along a line A-B shown in FIG. 1 according to one embodiment of the present disclosure;

FIG. 3 is a schematic view of light irradiating on an optical film according to one embodiment of the present disclosure;

FIG. 4 is a schematic view of cavities on an optical film according to one embodiment of the present disclosure;

FIG. 5 is a flowchart of a method of fabricating an optical film according to one embodiment of the present disclosure;

FIG. 6 is a schematic structural view of a display apparatus according to one embodiment of the present disclosure.

### DETAILED DESCRIPTION

The present disclosure will be described in further detail with reference to the accompanying drawings and embodiments in order to provide a better understanding of the technical solutions of the present disclosure by those skilled in the art.

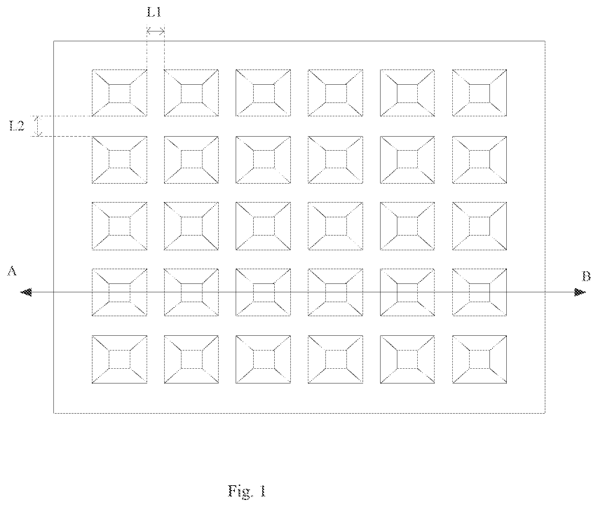

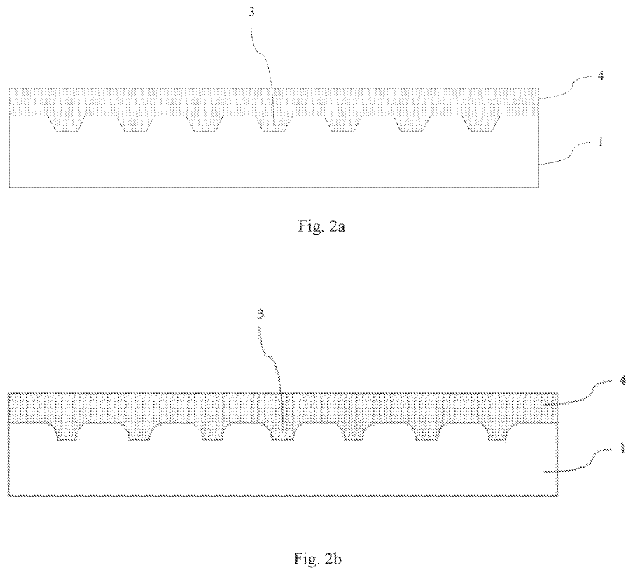

FIG. 1 is a plan view of an optical film according to one embodiment of the present disclosure. FIG. 2 is a cross-sectional view along a line A-B shown in FIG. 1. As shown in FIGS. 1 and 2, an optical film is provided. The optical film includes a substrate 1 and a planarization layer 4. Cavities 3 are provided on the substrate 1. A cross-sectional area of a cavity 3 parallel to a bottom surface thereof increases gradually along a direction away from the bottom surface. The planarization layer 4 is on a side of the substrate 1 having the cavities 3. A refractive index of the planarization layer 4 is larger than that of the substrate 1. The planarization layer 4 at least fills and levels up the cavities 3. A surface of the planarization layer 4 is flat. In one embodiment, a surface of the planarization layer is substantially parallel to the bottom surface of each of the cavities. “Substantially parallel” herein means that the two surfaces may form an intersecting angle of less than 5 degree.

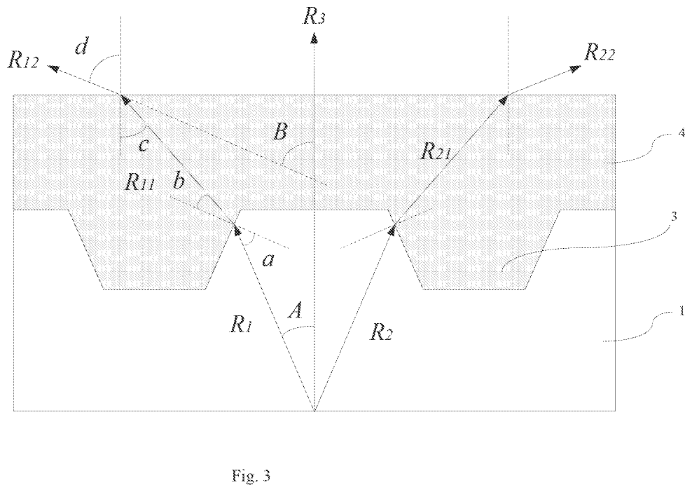

An optical film according to one embodiment of the present disclosure may be applied into a display substrate. The display substrate may be assembled with an array substrate into a cell to form a display panel. The optical film is on a light exiting side of the display panel. In one embodiment, the display substrate may be a color film substrate or an opposite substrate. In another embodiment, the optical film may also be used in an array substrate. A side of a substrate 1 of the optical film having the cavities 3 is at a light exiting side of the display panel. In one embodiment, as shown in FIG. 3, when a light beam R1 is incident on a side surface of a cavity 3, an angle between the light beam R1 and a normal line of the side surface thereof is an incident angle a. After the light beam enters a planarization layer 4, an angle between a light beam R11 and the normal line is an exit angle b. Since a refractive index of the substrate 1 is smaller than that of the planarization layer 4, the light beam R11 will be deflected toward the normal line according to Snell's Law. That is, the exit angle h is smaller than the incident angle a. When the light beam R11 is emitted from the planarization layer 4 into air, an angle between the light beam R11 and a normal line of an interface between the planarization layer 4 and the air is an incident angle c. An angle between an exit light beam R12 and the normal line of the interface is an exit angle d. Since a refractive index of air is smaller than that of the planarization layer 4, the angle d is greater than the angle c according to Snell's Law.

As shown in FIG. 3, a light beam R3 is perpendicularly incident onto a bottom surface of a cavity 3 of the substrate 1. An angle between the light beam R12 and the light beam R3 is B. An angle between the light beam R1 and the light beam R3 is A. The angle B is greater than the angle A. As such, incident lights may be refracted from side surfaces of a cavity 3 at different directions, thereby increasing ranges of light exiting angles. A light beam incident perpendicularly onto a bottom surface of a cavity 3 or a horizontal plane between cavities 3 are not refracted at an interface when passing through it. As a result, brightness of the light beam within a front viewing angle is maintained.

In one embodiment, there is a plurality of cavities 3 on the substrate 1. The plurality of cavities 3 are arranged in an array. That is, spacing between positive projections of any of two adjacent cavities 3 in a row direction or in a column direction on the substrate 1 is equal. As shown in FIG. 1, a distance L1 between two adjacent columns of cavities is equal to a distance L2 (L1=L2) between two adjacent rows of cavities. In one embodiment, the spacing is approximately in a range between 1 μm and 5 μm. In another embodiment, the spacing may also be adjusted according to a size of a panel. The cavities 3 on the substrate 1 of the display substrate according to the present embodiment are arranged in a matrix, that is, the cavities 3 are uniformly distributed. As such, light passing, through the substrate 1 can be uniformly dispersed. Accordingly, as a viewing angle is increased, a display of the panel is also uniform. A numerical range modified by “approximately” herein means that the upper and lower limits of the numerical range can vary by 10% thereof.

In one embodiment, each of the above-described cavities 3 has a shape of a regular polygonal prism. At such, light can be refracted to a same angle after passing through each side of the cavity 3, and the light emits uniformly. In one embodiment, the cavity 3 may have a shape of a regular quadrangular prism. In another embodiment, the cavity 3 may have a shape of a regular hexagonal prism or a regular octagonal prism. In another embodiment, the cavity has a shape of a hemisphere. In one embodiment, a side surface of the cavity is a planar surface. In another embodiment, a side surface of the cavity is a curved surface such as a concave surface or a convex surface, as shown in FIG. 2b.

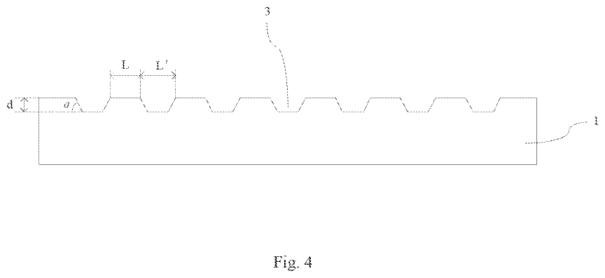

In one embodiment, a cavity 3 has a shape of a regular quadrangular prism as shown in FIG. 4. A length of a side of positive projection of the cavity 3 on a substrate 1 is L. A distance between two adjacent cavities 3 on the substrate is L′, which is the shortest distance between the two adjacent cavities. In one embodiment, L is equal or substantially equal to L′. Herein “substantially equal” means that the difference between L and L′ is less than 10% of the value of L. In one embodiment, L and L′ each may be approximately in a range between 1 μm and 5 μm. In another embodiment, L and L′ each may not be in a range between 1 μm and 5 μm, and may be determined based on effect of a final viewing angle being expanded. A depth of the cavity may depend on thickness of the substrate such as a glass substrate. In one embodiment, a depth of the cavity 3 may be approximately in a range between 500 nm to 1 μm. The depth of the cavity herein refers to a height of the cavity 3 in a direction perpendicular to its bottom surface. The depth of the cavity 3 may depend on a total thickness of the substrate 1 or may be adjusted according to specific situation such as difficulty of etching the substrate. In one embodiment, an angle between a side surface of the cavity 3 and an extending direction of the bottom surface thereof is approximately in a range between 30° to 70°. The angle may also be adjusted according to effect of a final viewing angle being expanded.

In one embodiment, the planarization layer 4 may be made of a transparent conductive material. The transparent conductive material may be inorganic materials such as indium tin oxide (ITO), indium zinc oxide (IZO), or fluorine doped tin oxide (FTO). The transparent conductive material may also be organic materials such as transparent conductive polymers, for example, poly (3,4-ethylenedioxythiophene) and its derivatives. One advantage of using a transparent conductive material is that, when an optical film of the present embodiments is used in a touch panel, a touch element needs to be fabricated on a light exiting side of the optical film. Static electricity is usually generated on a surface of the substrate 1 during the fabrication process. The static electricity can be discharged through the transparent conductive material, thereby avoiding electro-static discharge (ESD).

In one embodiment, a thickness of the planarization layer 4 may be approximately in a range between 1 μm to 2 μm. The thickness of the planarization layer 4 should at least fill and level up the cavities 3 and can be determined based on specific circumstance.

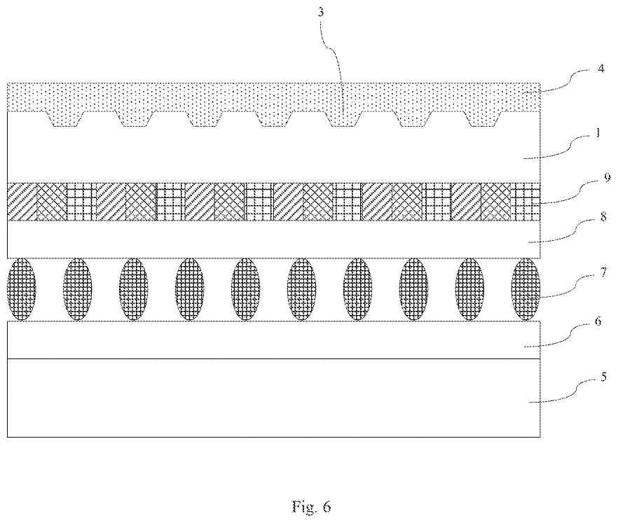

FIG. 6 is a schematic structural view of a display apparatus according to one embodiment of the present disclosure. As shown in FIG. 6, a display substrate including the above-described optical film is provided in the display apparatus according to one embodiment of the present disclosure.

In one embodiment, the display substrate may be a color film substrate. That is, a color film layer 9 is provided on a side of the substrate 1 away from the cavities. In another embodiment, the display substrate may be an opposite substrate, that is, a color film layer 9 is not included.

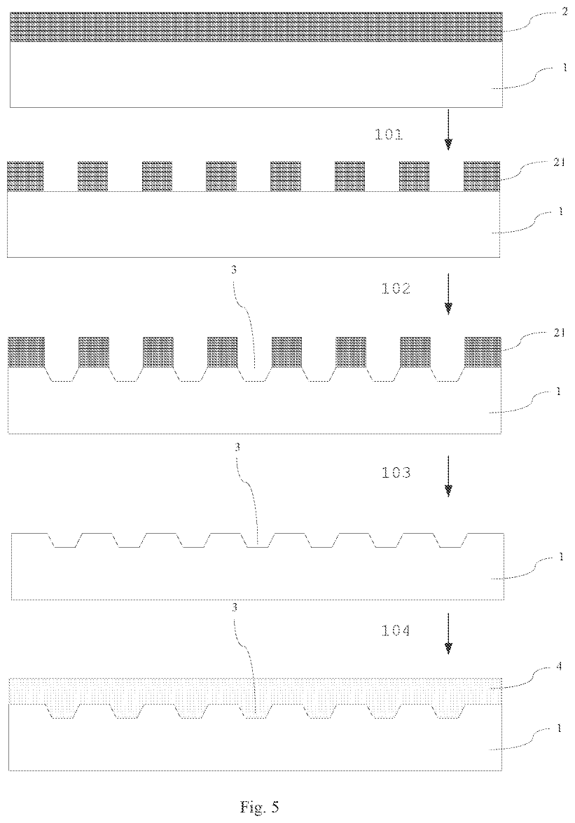

FIG. 5 is a flowchart of a method of fabricating an optical film according to one embodiment of the present disclosure. As shown in FIG. 5, the method for fabricating an optical film is provided. The display substrate may be the optical film in Embodiment 1. The fabrication method includes forming cavities 3 on a surface of the substrate and forming a planarization layer 4 on the surface of the substrate 1 having the cavities. An angle between a side surface and a bottom surface of the cavities 3 is an acute angle. The cavities may be formed by etching a substrate or a 3D printing technique.

In one embodiment, the method for fabricating the optical film are described in detail as follows:

During step 101, a layer of photoresist 2 is coated on a surface of a substrate 1, and then exposed and developed to form photoresist retention regions 21 and photoresist non-retention regions.

During step 102, the photoresist non-retention regions are etched to form cavities 3 by a plasma etching apparatus.

In one embodiment, a mixture gas of Ar and CHF₃ is used as etching gas to etch the substrate 1 with an inductively coupled plasma (ICP) etching apparatus. When the Ar inert gas is ionized into Ar in an etching chamber, the Ar⁺ can Obtain a lot of kinetic energy through self-bias acceleration of the ICP apparatus, thereby increasing bombardment effect of the plasma and assisting the plasma ionized from CHF₃ to etch the substrate 1. A power of an upper electrode of the ICP may be set at about 200 W. A power of an lower electrode thereof, which is to provide self-bias electrode power, may be set at about 50 W. As such, high-speed etching of the substrate 1 is achieved. An angle between a side surface of an etching cavity 3 and a bottom surface of the substrate 1 may be controlled by adjusting a ratio of Ar/CHF₃ in the mixture gas, a pressure of the etching chamber, and/or powers of the upper electrode and the lower electrode.

During step 103, the photoresist at the photoresist retention regions 21 is removed to form the substrate 1 having the cavities 3.

During step 104, a transparent conductive film, which may be an ITO film, having a thickness approximately in a range of 1 to 2 μm is formed on a surface of the substrate 1 having the cavities 3 by magnetron sputtering. An upper surface of the ITO film is planarized by a chemical mechanical planarization process or an anneal process to obtain a flat ITO thin film. That is, the planarization layer 4 is formed. In one embodiment, the planarization layer 4 at least fills and levels up the cavities 3. In addition, a surface of the formed planarization layer 4 is flat.

A display apparatus including a display substrate of Embodiment 1 is provided according to one embodiment of the present disclosure. As such, the display apparatus has wider viewing angles and better display effect.

In one embodiment, the display apparatus may be a liquid crystal display apparatus, an electroluminescent display apparatus, or any product or component with a display function, such as a liquid crystal panel, an electronic paper, an Organic Light-Emitting, Diode (OLED) panel, a mobile phone, a tablet computer, a television set, a monitor, a notebook computer, a digital photo frame, or a navigator etc. In the case of an OLED panel, the optical film is disposed on the outer surface of the package cover plate and can share one substrate with the package cover plate.

FIG. 6 is a schematic structural view of a liquid crystal display apparatus according to one embodiment of the present disclosure. As shown in FIG. 6, the liquid crystal display apparatus includes an array substrate, a color film substrate opposite the array substrate, and a liquid crystal layer 7 disposed between the array substrate and the color film substrate. The display substrate of Embodiment 1 may be the color film substrate in FIG. 6. In one embodiment, the display substrate includes a substrate 1 having cavities 3, a planarization layer 4, a color film layer 9, and an alignment layer 8. The array substrate includes a substrate 5 of the array substrate and an alignment layer 6.

The descriptions of the various embodiments of the present disclosure have been presented for purposes of illustration, but are not intended to be exhaustive or limited to the embodiments disclosed, Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

### DESCRIPTION OF SYMBOLS IN THE DRAWINGS

1: substrate
2: photoresist
21: photoresist retention region
3: cavity
4: planarization layer
5: substrate of an array substrate
6 and 8: alignment layer
7: liquid crystal layer
9: color film layer

1. An optical film, comprising:
a substrate; and
a planarization layer;
wherein a plurality of cavities are provided on a surface of the substrate, a cross-sectional area of each of the cavities parallel to a bottom surface thereof increases along a direction away from the bottom surface; and
the planarization layer is on the surface of the substrate having the cavities, and a refractive index of the planarization layer is larger than a refractive index of the substrate.

2. The optical film according to claim 1, wherein the plurality of cavities are arranged in an array.

3. The optical film according to claim 1, wherein the cavities each have a shape of a regular polygonal prism.

4. The optical film according to claim 3, wherein the regular polygonal prism is a regular quadrangular prism.

5. The optical film according to claim 4, wherein a length L of a side of a positive projection of each of the cavities on the substrate is substantially equal to a distance L′ between two adjacent cavities on the substrate.

6. The optical film according to claim 5, wherein L and L′ each are approximately in a range between 1 μm and 5 μm.

7. The optical film according to claim 1, an angle between a side surface of each of the cavities and the bottom surface thereof is approximately in a range between 110° to 150°.

8. The optical film according to claim 1, wherein a depth of each of the cavities is approximately in a range between 500 nm to 1 μm.

9. The optical film according to claim 1, wherein a thickness of the planarization layer is approximately in a range between 1 μm to 2 μm.

10. The optical film according to claim 1, wherein the planarization layer at least fills and levels up the cavities.

11. The optical film according to claim 1, wherein a surface of the planarization layer is substantially parallel to the bottom surface of each of the cavities.

12. The optical film according to claim 1, wherein the planarization layer is made of a transparent conductive material.

13. The optical film according to claim 12, wherein the transparent conductive material is indium tin oxide.

14. A display substrate comprising the optical film according to claim 1.

15. The display substrate according to claim 14, wherein the display substrate further comprises a color film layer on a side of the substrate away from the cavities.

16. A method for fabricating an optical film, comprising:
providing a substrate;
forming a cavity on a surface of the substrate, wherein a cross-sectional area of the cavity parallel to a bottom surface of the cavity increases along a direction away from the bottom surface; and
forming a planarization layer on the surface of the substrate having the cavity.

17. The method for fabricating an optical film according to claim 16,
wherein forming the cavity on the surface of the substrate comprises:
coating a layer of photoresist on the surface of the substrate and forming photoresist retention regions and photoresist non-retention regions on the substrate;
etching the photoresist non-retention regions to form the cavity by a plasma etching apparatus; and
removing the photoresist at the photoresist retention regions.

18. The method for fabricating an optical film according to claim 16,
wherein forming the planarization layer on the surface of the substrate having the cavity comprises:
forming the planarization layer on the surface of the substrate having the cavity by a magnetron sputtering method.

19. A display apparatus comprising the display substrate according to claim 14.
